(19) United States
(12) Patent Application Publication
(10) Pub. No.: US 2026/0282774 A1
(43) Pub. Date: Sep. 17, 2026

(54) METHOD OF MANUFACTURING SILICON WAFER AND SILICON WAFER

(71) Applicant: GLOBALWAFERS JAPAN CO., LTD., Kitakanbara-gun (JP)

(72) Inventors: Hiroya IWASHIRO, Kitakanbara-gun (JP); Haruo SUDO, Kitakanbara-gun (JP); Ken HAYAKAWA, Kitakanbara-gun (JP); Yuma KOBAYASHI, Kitakanbara-gun (JP)

(21) Appl. No.: 19/558,441

(22) Filed: Mar. 6, 2026

(30) Foreign Application Priority Data
Mar. 14, 2025 (JP) 2025-041315

(51) Int. Cl. H10P 14/60; H10P 70/00

(52) U.S. Cl. CPC H10P 14/6309; H10P 14/6322; H10P 70/237

(57) ABSTRACT

A method of manufacturing silicon wafers that suppresses BMD precipitation while avoiding risks from metal contamination is provided. This method of manufacturing silicon wafers involves a first RTO where a planarized silicon wafer W, fabricated from a single-crystal ingot grown by the CZ method, is heated to a first maximum temperature reached of 1300° C. to 1380° C. in an oxidizing atmosphere having an oxygen partial pressure of 25% to 100%, held at the first maximum temperature reached for 5 s or longer, an oxide film removal step where the silicon wafer W obtained from the first RTO is cleaned with hydrofluoric acid, and a second RTO where the silicon wafer W obtained from the oxide film removal step is heated to a second maximum temperature reached of 1050° C. to less than 1300° C. in an oxidizing atmosphere, and held at the second maximum reach temperature for 5 s or longer.

### TECHNICAL FIELD

The present invention relates to a method of manufacturing silicon wafers suitable for use as substrates for semiconductor devices and a silicon wafer.

### BACKGROUND ART

Silicon wafers to be used as substrates for semiconductor devices contain defects called atomic vacancies (V). The concentration of these atomic vacancies is correlated with the density of oxygen precipitates (bulk microdefects, BMDs) that are formed during heat treatment, and the atomic vacancies are considered to contribute to the nucleation of BMDS.

Atomic vacancies in a silicon wafer are not present in isolation, but form vacancy-oxygen complexes (VOₓ) through bonding with oxygen dissolved from a quartz crucible during crystal growth by the Czochralski (CZ) method, or void defects are formed through aggregation of the atomic vacancies. The BMDs formed from atomic vacancies readily bind to metals and function as gettering sites for metal impurities that have penetrated the silicon wafer.

Meanwhile, BMDs can sometimes contribute to dislocation generation. In such cases, suppressing BMD precipitation is required as a countermeasure against dislocation generation. Patent Literature 1 discloses technology that suppresses BMD precipitation through a heat treatment method involving two-stage RTO (rapid thermal oxidation) on a silicon wafer.

Specifically, this heat treatment method includes a first heat treatment step (a first RTO, or rapid thermal process in an oxidizing atmosphere), in which the silicon wafer is heated to a temperature of 1300° C. or more to 1380° C. or less in an oxidizing atmosphere with an oxygen partial pressure of 25% to 100%, and held for not less than 5 seconds and then, cooled to a temperature of 800° C. or lower at a cooling rate not greater than 120° C./s, and a second heat treatment step (a second RTO), in which the silicon wafer is heated to a temperature of 1150° C. or more and 1220° C. or less in an oxidizing atmosphere with an oxygen partial pressure of 25% to 100%, and held for not less than 5 seconds and then, cooled at a cooling rate not greater than 120° C./s. The second RTO is performed continuously after the first RTO. This eliminates atomic vacancies in the silicon wafer surface layer during the first RTO and those in the bulk region during the second RTO.

### CITATION LIST

### Patent Literature

PTL 1: JP-A-2019-192831

### SUMMARY OF INVENTION

### Technical Problem

However, in the heat treatment method described in PTL 1, since a second RTO is performed continuously after the first RTO, there is a risk that metal contamination occurring on the silicon wafer due to the RTP apparatus during the first RTO will diffuse into the interior of the silicon wafer during the second RTO.

That is, since the heat treatment method described in Patent Document 1 reduces atomic vacancies and suppresses BMD precipitation through two-stage RTO, even when metal contamination occurs, there is a risk that the effectiveness of BMDs, which function as gettering sites for metal impurities, would be limited.

The present invention was made in view of the above issues and aims to provide a manufacturing method for silicon wafer and a silicon wafer capable of suppressing BMD precipitation while avoiding the risks associated with metal contamination.

### Solution to Problem

The manufacturing method for a silicon wafer of the present invention involves a first heat treatment step of heating a silicon wafer, which is prepared by slicing a single-crystal silicon ingot grown by the CZ method and planarized, in an oxidizing atmosphere with an oxygen partial pressure of 25% to 100%, to a first maximum temperature reached of 1300° C. or higher and 1380° C. or lower, and holding at the first maximum temperature reached for 5 or longer, an oxide film removal step of cleaning the silicon wafer obtained by the first heat treatment step with hydrofluoric acid; and a second heat treatment step of heating the silicon wafer obtained by the oxide film removal step to a second maximum temperature reached of 1050° C. to less than 1300° C. in an oxidizing atmosphere with an oxygen partial pressure of 25% to 100%, and holding at the second maximum temperature reached for 5 s or longer.

According to the manufacturing method for a silicon wafer of the present invention, the first heat treatment process is performed to eliminate vacancy-oxygen complexes (VOₓ) and voids, and an oxide film removal process is performed to enhance the atomic vacancy elimination effect and to remove metal contamination in the wafer W caused by the RTP apparatus. A second heat treatment process is performed to eliminate atomic vacancies remaining in the bulk region. Therefore, a silicon wafer can be obtained where BMD precipitation is effectively suppressed while avoiding risks due to metal contamination.

It is further preferable that the manufacturing method for a silicon wafer according to the present invention additionally includes a polishing step to polish the surface and surface layer of the silicon wafer obtained by the second heat treatment step. Moreover, it is more preferable that the partial pressure of oxygen in the oxidizing atmosphere during the first heat treatment step and the second heat treatment step is 100%. Furthermore, in the oxide film removal step, it is preferable to clean the surface of the silicon wafer obtained from the first heat treatment step with a 10% or higher hydrofluoric acid aqueous solution for 10 s or longer. Moreover, it is preferable that the oxygen concentration of the silicon wafer before the first heat treatment step is 1.0×10¹⁸/cm³ to 1.5×10¹⁸/cm³.

The silicon wafer of the present invention is a silicon wafer that is subjected to two-stage RTO on a silicon wafer obtained by slicing and planarizing a single-crystal silicon ingot grown by the CZ method, characterized in that, when held at 780° C. for 3 hours in an oxidizing atmosphere followed by holding at 1000° C. for 16 hours, the defect density of 20 nm or larger, as observed by IR tomography, is lower than 1×10⁸/cm³.

### Advantageous Effects of Invention

The manufacturing method of silicon wafers according to the present invention allows for the suppression of the BMD precipitation while avoiding risks due to metal contamination.

### BRIEF DESCRIPTION OF DRAWINGS

FIG. 1 is a conceptual cross-sectional view illustrating an example of a single-wafer rapid thermal processing (RTP) apparatus used for heat treatment in a method of manufacturing a silicon wafer according to the present invention.

FIG. 2 is a flowchart illustrating an example of the method of manufacturing a silicon wafer according to the present invention.

FIG. 3 is a conceptual view showing a heat treatment sequence.

FIGS. 4A to 4F are schematic views showing the behaviors of point defects during heat treatment.

FIG. 5 is a view showing the defect density 20 nm or more as observed by IR tomography.

FIG. 6 is a view showing captured images in a cross-section of a wafer at a depth of 350 μm from the wafer surface.

### SUMMARY OF INVENTION

### Description of Embodiments

Embodiments of the present invention of the method of manufacturing a silicon wafer and a silicon wafer will be described in detail with reference to drawings. The embodiments do not limit the scope of the invention. In the specification and drawings of the present invention, identical reference numerals may be used to denote elements that can be described in the same manner, and redundant descriptions thereof may be omitted.

### <Abstract of Manufacturing Method>

The method of manufacturing a silicon wafer of the present embodiment includes a step of first heat treatment (referred to as first RTO) in which a silicon wafer, which is sliced and planarized from a single-crystal silicon ingot grown by the CZ method, is heated to a first maximum temperature reached of 1300° C. or higher and 1380° C. or lower in an oxidizing atmosphere with an oxygen partial pressure of 25% to 100%, and held at that temperature for 5 seconds or longe, a step of oxide film removal that cleans the silicon wafers obtained from the first heat treatment process with hydrofluoric acid, and a step of second thermal treatment (referred as to second RTO), in which the silicon wafer obtained from the oxide film removal process is heated to a second maximum temperature reached of 1050° C. or higher and less than 1300° C. in an oxidizing atmosphere with an oxygen partial pressure of 25% to 100%, and held at the second maximum temperature reached for 5 s or longer. Hereinafter, the silicon wafer may be referred to simply as “wafer” in the following embodiments.

The atomic vacancies contained in a silicon single crystal grown by the CZ method form vacancy-oxygen complexes (VOₓ) by bonding with oxygen atoms, or form void defects bonded with other atomic vacancies. Since the concentration of atomic vacancies is correlated with the precipitated BMD density, vacancy-oxygen complexes the (VOₓ) and voids in the wafer are considered to serve as BMD precipitation nuclei.

In the method of manufacturing a silicon wafer of the present embodiment, defects originating from atomic vacancies contained in wafer W, where atomic vacancies exist predominantly, that is, vacancy-oxygen complexes (VOₓ) and voids, are eliminated by performing RTP (RTO) in an oxidizing atmosphere. Since it is known that RTO at a temperature of 1300° C. or more eliminates voids formed during crystal growth, in the present embodiment, the first RTO is performed in which a wafer W is heated to a first maximum temperature reached of 1300° C. or higher and 1380° C. or lower in an oxidizing atmosphere, and held at the first maximum temperature reached for 5 s or longer. When RTO is performed at a temperature of 1300° C., since the thermal equilibrium density of atomic vacancies becomes higher than that of silicon interstitials, additional atomic vacancies are introduced into the bulk region, and VO₄, which is a vacancy bonded with four oxygen atoms, is formed. In the first RTO, BMD precipitation in the wafer surface layer is suppressed, whereas BMD precipitation in the bulk region is not suppressed.

Thereafter, the wafer W is heated to the second maximum temperature reached of 1050° C. or higher and less than 1300° C. in an oxidizing atmosphere, and maintained for 5 s or longer at the second maximum temperature reached, which is the second RTO performed, thereby injecting silicon interstitials by an oxide film formed on the wafer surface and eliminating atomic vacancies introduced by the first RTO.

This enables the manufacture of a wafer W without atomic-vacancy-originated defects in both the wafer surface layer and the bulk region, using a single-crystal silicon ingot predominantly containing atomic vacancies.

As described above, in the case of the elimination of the atomic vacancies introduced by the first RTO, when the second RTO is performed while the oxide film formed by the first RTO is attached to the wafer surface, the elimination of atomic vacancies may be less effective due to the already relieved state of distortions on the boundary of the oxide film. Accordingly, in the present embodiment, an oxide film removal process in which the wafer surface is cleaned using hydrofluoric acid (HF) is preferably performed after the first RTO and before the second RTO to enhance the effectiveness of the elimination of atomic vacancies by the second RTO.

Cleaning of the wafer surface with hydrofluoric acid before the second RTO can eliminate the oxide film on the wafer surface and prevent a new natural oxide film from forming by terminating dangling bonds on the surface with hydrogen. This oxide film removal process with hydrofluoric acid before the second RTO can also inhibit BMD precipitation at a lower temperature than the conventional method.

Even when metal contamination occurs on the wafer W due to the RTP apparatus during the first RTO, the risk of the dispersion of the metal contaminants into the interior of the wafer may be reduced during the second RTO because the oxide film removal process can eliminate the metal contamination.

### <RTP Apparatus>

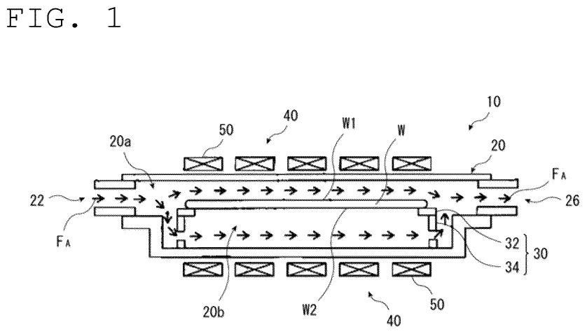

FIG. 1 is a conceptual cross-sectional view showing an example of a single-wafer RTP apparatus used for heat treatment (RTP) in the method of manufacturing a silicon wafer according to the present invention.

The RTP apparatus 10 shown in FIG. 1 is equipped with a reaction chamber 20 that accommodates a silicon wafer W and performs heat treatment; a wafer support 30 that holds the wafer W and is installed within the reaction chamber 20; and a heater 40 that heats the wafer W. When the wafer W is held on the wafer support 30, two spaces are formed; a first space 20a which is surrounded by the inner wall of the reaction chamber 20 and the front surface W1 (the device-formed surface) of the wafer W is formed, and a second space 20b which is surrounded by the inner wall of the reaction chamber 20 and the back surface W2 of the wafer W, which is opposite to the front surface W1.

The reaction chamber 20 includes a supply port 22, through which an atmosphere gas FA (solid line arrow) is supplied to the first space 20a and second space 20b, and an exhaust port 26 through which the supplied atmosphere gas FA is exhausted from the first space 20a and second space 20b. The reaction chamber 20 is made of quartz, for example.

The wafer support 30 includes a ring-shaped susceptor 32 that holds the outer periphery of the back surface W2 of the wafer W and a rotator 34 that holds the susceptor 32 and rotates the susceptor 32 about the axis that is the center of the wafer W. The susceptor 32 is made of silicon carbide, for example, and has an oxide film coating on its surface.

The heater 40 heats the wafer W from both sides by lamp heating using irradiating light from a plurality of halogen lamps 50 disposed outside the reaction chamber 20, above the front surface W1 and below the back surface W2 of the wafer W held by the wafer support 30.

When performing heat treatment using the RTP apparatus 10 shown in FIG. 1, a wafer W is introduced into the reaction chamber 20 through a wafer introduction port (not shown) provided in the reaction chamber 20. The outer periphery of the backside W2 of the wafer W is held on a ring-shaped susceptor 32 within the wafer support 30. Then, while supplying atmosphere gas FA and rotating the wafer W, the wafer W is heated by the heater 40.

### Specific Example of Manufacturing Method

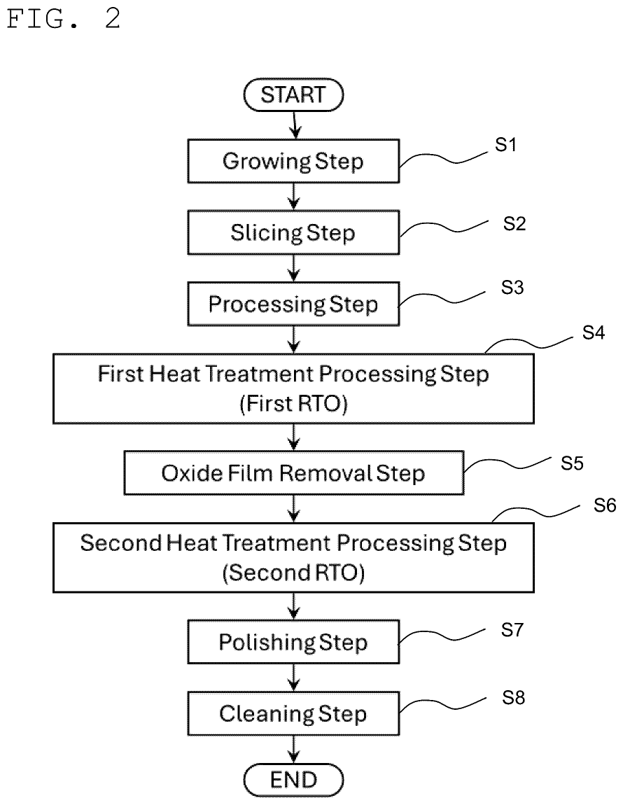

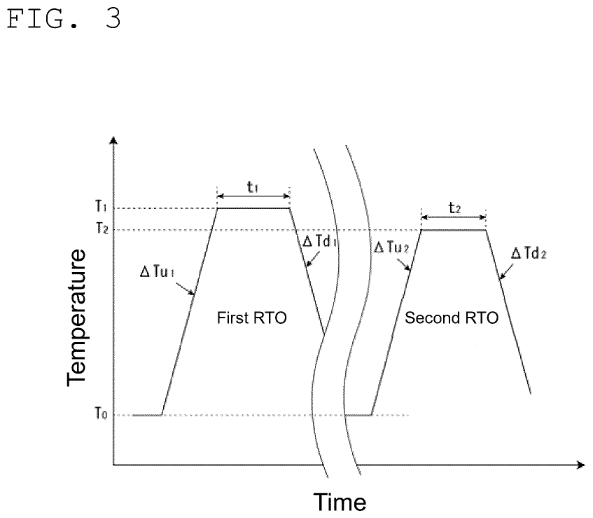

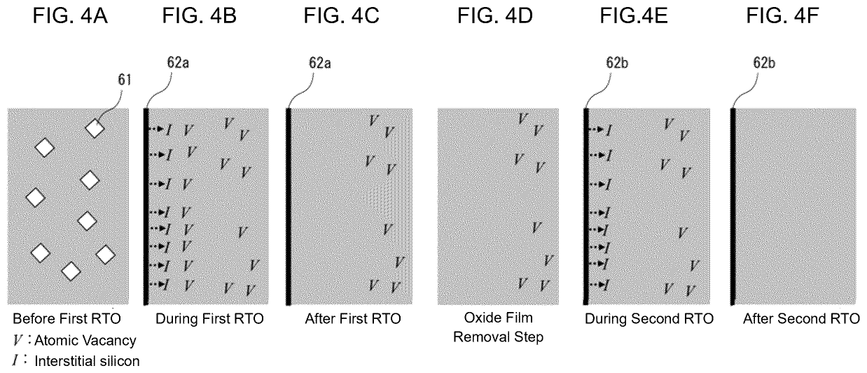

Next, an embodiment of the method of manufacturing a silicon wafer according to the present invention will be specifically described with reference to drawings. FIG. 2 is a flowchart illustrating an example of the method of manufacturing a silicon wafer according to the present invention. FIG. 3 is a conceptual view showing a heat treatment sequence. FIGS. 4A to 4F are schematic views showing the behaviors of point defects during heat treatment.

As shown in FIG. 2, the method of manufacturing a silicon wafer of the present invention includes a growing step for growing a single-crystal silicon ingot by the CZ method (Step S1), a slicing step for manufacturing into disk-shaped wafers W (Step S2) by slicing the grown single-crystal silicon ingot, a processing step for performing a planarization process to the surface of the disk-shaped wafer W (Step S3), the first heat treatment step (a first RTO; Step S4), the oxide film removal step (Step S5), the second heat treatment step (a second RTO; Step S6), a polishing step for polishing the front surface and the surface layer of the wafer W obtained by the second RTO (Step S7), and a cleaning step for performing single-wafer spin cleaning on the wafer W after a polishing step (Step S8).

As described above, in the method of manufacturing silicon wafer of the present embodiment, a two-step RTO is performed on the wafers W produced by slicing a single-crystal silicon ingot grown by the CZ method and then planarizing the wafers.

FIG. 2 is a flowchart in which the growth of single-crystal silicon ingots using the CZ method (Step S1) is shown, which is a well-known process. Specifically, polycrystalline silicon filled into a quartz crucible is heated to form molten silicon. A seed crystal is then brought into contact with the surface of this molten silicon from above the liquid surface. The seed crystal and quartz crucible are rotated while being pulled upward, expanding the diameter to the desired size to grow a straight body section, thereby producing a single-crystal silicon ingot.

The obtained single-crystal silicon ingot is processed into a planarized wafer W using a known method (Step S2 and Step S3). Specifically, the single-crystal silicon ingot is sliced into wafer pieces using an inner-perimeter blade or wire saw, etc. (Step S2), Subsequently, the sliced wafer W undergoes peripheral chamfering, rough grinding to a specified thickness while removing cutting damage formed during slicing, i.e., lapping, chemical etching to remove fine distortions and scratches introduced by lapping, and polishing (Step S3), yielding a planarized wafer W. Note that the processing steps described here are exemplary, and this embodiment is not limited to these specific processing steps.

Atomic vacancies contained in a single-crystal silicon ingot grown by the CZ method in steps S1 through S3 form vacancy-oxygen complexes (VOₓ) or voids as described above. As shown in FIG. 4A, these vacancy-oxygen complexes (VOₓ) or voids 61 are present in planarized wafers W after the processing steps (for convenience, FIG. 4A shows only voids 61).

Next, for the planarized wafer W, the first RTO (step S4), the oxide film removal step (step S5), and the second RTO (step S6) are sequentially performed under predetermined conditions. In the present embodiment, the oxygen concentration (oxygen concentration in the crystal) of the wafer W before performing the first RTO may be preferable if 1.5×10¹⁸/cm³ or less. For example, it is more preferably 0.8×10¹⁸/cm³ to 1.5×10¹⁸/cm³, and most preferably 1.0×10¹⁸/m³ to 1.5×10¹⁸/cm³.

As shown in FIG. 3, in the thermal processing sequence applied to the method of manufacturing a silicon wafer of the present embodiment, a wafer W is first placed on a susceptor 32 within the reaction chamber 20 of the RTP apparatus 10, which is maintained at a desired temperature T₀.

Then, the first RTO is performed on this wafer W (step S4). Specifically, in an oxidizing atmosphere, the wafer W is rapidly heated at a first heating rate ΔTu₁ to a first maximum temperature reached T₁, held at the first maximum temperature reached T₁ for a first holding time t₁, and then cooled at a first cooling rate ΔTd₁ to a desired temperature. Upon performing the first RTO, an oxide film 62a having a thickness of, for example, 10 to 50 nm is formed on the wafer surface. At the same time, silicon interstitials (I) are injected from the interface of the oxide film 62, whereby vacancy-oxygen complexes (VOₓ) and aggregated voids 61 are eliminated, allowing atomic vacancies (V) to diffuse (see FIG. 4B). After the first RTO, the silicon interstitials (I) and atomic vacancies (V) present in the surface layer of the wafer W are eliminated by recombination. Whereas, since the thermal equilibrium concentration of atomic vacancies (V) becomes higher than the thermal equilibrium concentration of the silicon interstitials (I), atomic vacancies (V) remain in the bulk region (see FIG. 4C).

After performing the first RTO, the oxide film removal process (step S5) eliminates the oxide film 62a formed on the wafer surface. At this time, the oxide film 62a is removed by performing hydrofluoric acid cleaning on the wafer surface. Specifically, after removing the wafer W from the RTP apparatus 10 following RTO, the oxide film 62a is removed by supplying a hydrofluoric acid aqueous solution with a fluoride concentration of 10% or higher to the wafer surface for 10 s or longer using a single-wafer spin cleaning process (cleaning using a spin cleaning apparatus) (see FIG. 4D).

Next, the wafer W, after the oxide film is removed, is mounted on the susceptor 32 in the reaction chamber 20 of the RTP apparatus 10, which is kept at the desired wafer temperature T₀, before performing the second RTO. (See the heat treatment sequence shown in FIG. 3.)

Then, the second RTO is performed on the wafer W with the oxide removed (Step S6). Specifically, in an oxidizing atmosphere, the wafer W is rapidly heated to a second maximum temperature reached T₂ at a second heating rate ΔT₂, held at the second maximum temperature reached T₂ for a second holding time t₂, and then cooled to a desired temperature at a second cooling rate ΔTd₂. Upon performing the second RTO, an oxide film 62b, for example, 10 to 50 nm thick, is formed on the wafer surface, and silicon interstitials (I) are injected from the interface of the oxide film 62b (see FIG. 4E). After the second RTO, the injected silicon interstitials (I) and the atomic vacancies (V) remaining in the bulk region are eliminated by recombination (see FIG. 4F).

As described above, in the method for manufacturing a silicon wafer of the present embodiment, a two-stage RTO, with an oxide film removal step interposed therebetween, is performed on the planarized wafer W. In the first RTO, vacancy-oxygen complexes (VOₓ) and precipitated voids 61 are eliminated. Furthermore, atomic vacancies (V) remaining in the bulk region are eliminated in the second RTO after the oxide film 62a formed in the first RTO is removed.

Specifically, in the first RTO, the planarized wafer W, which has been processed in steps S1 to S3, is heated to a first maximum temperature reached T₁ of 1300° C. or higher but not exceeding 1380° C. at a first heating rate ΔTu₁ of 10° C./s or more in an oxidizing atmosphere with an oxygen partial pressure of 25% to 100%. After holding the wafer W at the first maximum temperature reached T₁ for a first hold time t₁ of 5 s or longer, the wafer W is cooled to the desired temperature at a first cooling rate ΔTd₁ of 25° C./s or more and 120° C./s or less.

In the second RTO, the wafer W, from which the oxide film is removed in step S5, is heated at a second heating rate ΔTu₂ of 10° C./s or more to a second maximum temperature reached T₂ of 1050° C. or higher but not exceeding 1300° C. in an oxidizing atmosphere with an oxygen partial pressure of 25% to 100%. After holding the wafer W at the second maximum temperature reached T₂ for a second holding time t₂ of 5 s or longer, the wafer W is cooled to the desired temperature at a second cooling rate ΔTd₂ of 25° C./s or more and 120° C./s or less.

As described above, after the first RTO (step S4), the oxide film removal step (step S5), and the second RTO (step S6) are performed in this order, a polishing step (step S7) for polishing the surface and surface layer of the wafer W, from which the atomic vacancies are eliminated, and a cleaning step (step S8) for single-wafer spin cleaning on the polished wafer W are performed in the present embodiment.

In the present embodiment, a wafer W, in which BMD precipitation is inhibited, is obtained from a single-crystal silicon ingot predominantly containing atomic vacancies by performing the method of manufacturing a silicon wafer described above (steps S1 to S8).

Furthermore, single-crystal silicon ingots are not limited to those grown by the CZ method; for example, ingots grown by the FZ method can also be used. Additionally, the dissolved oxygen concentration in wafer W before the first RTO should be between 1.0×10¹⁸/cm³ and 1.5×10¹⁸/cm³ to maintain a high dissolved oxygen concentration after RTO. However, it is not specifically limited to this range.

### <Detailed Description of Two-Stage RTO>

The first and second RTO will be described in further detail.

### <First RTO>

When RTP (RTO) is performed in an oxidizing atmosphere, oxidation of the wafer surface injects silicon interstitials into the wafer surface layer, rendering it supersaturated and eliminating vacancy-oxygen complexes (VOₓ) and voids 61 present in the wafer surface layer. Note that, as the oxygen concentration on the wafer surface increases, oxygen contained in COPs on the wafer surface and in oxide films formed on the inner walls of voids becomes less soluble in the wafer, making it difficult to reduce grown-in defects on the wafer surface. However, this region is removed by subsequent processes such as polishing.

The oxidizing atmosphere preferably has an oxygen partial pressure of 25% or more to 100%. An oxygen partial pressure of 100% is particularly preferable for promoting oxidation of the wafer surface. Oxygen gas is preferably employed as the oxidizing atmosphere, while an inert gas such as argon is preferably used to adjust the oxygen partial pressure.

### <First Heating Rate, First Maximum Temperature Reached, First Holding Time, First Cooling Rate>

As shown in FIG. 3, the wafer W held at the desired temperature T₀ of 500° C., for example, is heated to the first maximum temperature reached T₁. In this case, the first heating rate ΔTu₁ is preferably 10° C./s or more to 150° C./s or less. If the first heating rate ΔTu₁ is less than 10° C./s, oxygen precipitation nuclei, which are grown-in defects (such as voids 61), may grow into BMDs before disappearing, which is undesirable. In addition, if the first heating rate ΔTu₁ exceeds 150° C./s, it is undesirable because slips may occur in the wafer W due to its inability to withstand the excessively rapid temperature changes.

The first maximum temperature reached T₁ is preferably 1300° C. or higher and 1380° C. or lower. If the first maximum temperature reached T₁ is less than 1300° C., voids 61 and vacancy-oxygen complexes (VOₓ) become difficult to eliminate. If it is above 1380° C., the wafer surface sublimates, making this range undesirable. The first maximum temperature reached T₁ refers to an average temperature, a nine-point average temperature, for example, measured at multiple points in the radial direction within the wafer plane at the lower portion of the wafer, using a radiation thermometer (not shown) arranged around the wafer support 30, which supports the wafer W when it is placed in the RTP apparatus 10.

The first holding time, t₁, is preferably 5 s or longer. If the first holding time is shorter than 5 seconds, this is undesirable because vacancy-oxygen complexes (VOₓ) and voids 61 may remain. In addition, if the first holding time exceeds 40 s, this is undesirable because slips may occur. A first holding time t₁ of 10 s or more and 30 s or less is particularly preferable.

The first cooling rate ΔTd₁ is preferably 25° C./s or more and 120° C./s or less. If the first cooling rate ΔTd₁ exceeds 120° C./s, this is undesirable because slips tend to occur in the wafer W due to thermal stress. In addition, if the first cooling rate ΔTd₁ is lower than 25° C./s, this is undesirable because impurities (e.g., Ni), even if present in the wafer in minute amounts, may precipitate as silicides in the vicinity of the surface.

### <Second RTO>

By performing the RTP (RTO) in an oxidizing atmosphere, oxidation of the wafer surface injects silicon interstitials into the wafer surface layer, resulting in the silicon interstitials becoming the predominant point defect species.

The oxidizing atmosphere preferably has an oxygen partial pressure of 25% or more to 100%. An oxygen partial pressure of 100% is particularly preferable for promoting oxidation of the wafer surface. Oxygen gas is preferably employed as the oxidizing atmosphere, while an inert gas such as argon is preferably used to adjust the oxygen partial pressure.

### <Second Heating Rate, Second Maximum Temperature Reached,

### Second Holding Time, Second Cooling Rate>

As shown in FIG. 3, the wafer W held at the desired temperature T₀ of 500° C., for example, is heated to the second maximum temperature reached T₂. In this case, the second heating rate ΔTu₂ is preferably 10° C./s or more to 150° C./s or less. If the second heating rate ΔTu₂ is less than 10° C./s, this is undesirable because voids formed by aggregated atomic vacancies may promote the formation of oxygen precipitation nuclei and grow into BMD before the residual atomic vacancies disappear. In addition, if the second heating rate ΔTu₂ exceeds 150° C./s, this is undesirable because slips may occur in the wafer W due to its inability to withstand the excessively rapid temperature changes.

The second maximum temperature reached T₂ is preferably 1050° C. or higher and less than 1300° C. If the second maximum temperature reached T₂ is below 1050° C., atomic vacancies remaining in the bulk region become difficult to eliminate. If the temperature is 1300° C. or higher, this is undesirable because vacancies become predominant and their concentration increases. The second maximum temperature reached T₂ similar to the first RTO, refers to an average temperature, a nine-point average temperature, for example, measured at multiple points in the radial direction within the wafer plane at the lower portion of the wafer, using a radiation thermometer (not shown).

The second holding time t₂ is preferably 5 s or longer and 30 s or shorter. If the second holding time t₂ is shorter than 5 seconds, this is undesirable because atomic vacancies may remain. In addition, if the second holding time exceeds 30 s, the process is undesirable because it is more likely to be affected by metal contamination from the RTP apparatus 10.

The second cooling rate ΔTd₂ is preferably 25° C./s or more and 120° C./s or less. If the second cooling rate ΔTd₂ exceeds 120° C./s, this is undesirable because slips tend to occur in the wafer W due to thermal stress. In addition, if the second cooling rate ΔTd₂ is lower than 25° C./s, this is undesirable because metal impurities (e.g., Ni), even if present in the wafer in minute amounts, may precipitate as silicides in the vicinity of the surface.

When two-step RTO is performed, the oxygen concentration in the vicinity of the surface of the wafer W increases to its thermal equilibrium concentration, which may result in the retention of grown-in defects. Because of this, polishing (step S7) is performed 1 μm to 10 μm, for example, from the surface of the wafer W, after the second RTO is performed.

### <Silicon Wafer>

In the method of manufacturing silicon wafer of the present embodiment, performing two-step RTO with an oxide film removal step in between can eliminate atomic vacancies in both the surface layer and bulk region of the wafer W. As a result, the wafer W manufactured by the method of manufacturing silicon wafer of the present embodiment (steps S1 to S8) has a defect density of less than 1×10⁸/cm³ for defects having a size of 20 nm or larger, as observed by IR tomography, after being held at 780° C. for 3 hours and then 1000° C. for 16 hours in an oxidizing atmosphere.

In IR tomography, defects contained in the wafer W can be detected by irradiating the wafer surface with laser light and detecting light that is scattered through interaction with defects present in the wafer W. Defects detected by this method are not limited to BMDs, and void defects and other types of defects can also be detected as long as they are not less than the threshold size.

### Advantageous Effects

As described above, the method of manufacturing a silicon wafer of the present embodiment includes a first RTO (a first heat treatment step) where the silicon wafer W, which is sliced from a single-crystal silicon grown by the Czochralski method and planarized, is heated to a first maximum temperature reached of 1300° C. or higher and 1380° C. or lower, and held at the first maximum temperature reached for 5 s or longer in an oxidizing atmosphere with an oxygen partial pressure of 25% to 100%, an oxide film removal step where the silicon wafer W obtained after the first RTO is cleaned with a hydrofluoric acid, and a second RTO (a second heat treatment step) where the silicon wafer subjected to the oxide removal step, is heated to a second maximum temperature reached of 1050° C. or higher and 1300° C. or lower, and held at the second maximum temperature reached for 5 s or longer in an oxidizing atmosphere with an oxygen partial pressure of 25% to 100%.

Using the method of manufacturing silicon wafer of the present embodiment, a silicon wafer W in which BMD precipitation is effectively suppressed while avoiding the risk of metal contamination, can be obtained by performing a first RTO to eliminate vacancy-oxygen complexes (VOₓ) and voids 61, then performing an oxide film removal step to enhance the elimination of atomic vacancies and to remove metal contamination originating from the RTP apparatus 10 to silicon wafer W, and thereafter performing a second RTO to eliminate atomic vacancies remaining in the bulk region.

In the method of manufacturing a silicon wafer of the present embodiment, it is preferable to further perform a polishing step in which the surface and the surface layer of the silicon wafer W obtained by the second RTO are polished. The oxygen partial pressure in the oxidizing atmosphere of 100% is particularly preferable in the first and second RTO. In the oxide film removal step, the surface of the silicon wafer W obtained in the first RTO is preferably cleaned with a 10% or more hydrofluoric acid aqueous solution for 10 s or longer. Note that the oxygen concentration of the silicon wafer W before the first RTO is preferably 1.0×10¹⁸/cm³ to 1.5×10¹⁸/cm³.

The present invention is not limited to the above-described embodiments, which are merely illustrative. Various modifications and changes that substantially embody the technical concept described in the appended claims and achieve the same effects are included within the scope of the present invention.

### EXAMPLES

Next, the method of manufacturing a silicon wafer of the present invention will be further described with reference to examples. The present invention is not limited to the following examples.

### Referential Examples, Comparative Examples, Examples

The method of manufacturing silicon wafer according to the present invention shown in FIG. 2 (Steps S1 to S8) was performed; that is, after performing a slicing step and a machining step by a well-known method, the manufacturing steps shown in Table 1 below were performed under the manufacturing conditions described below, and further, a polishing step and a cleaning step were performed by well-known methods, thereby preparing 300 mm-diameter wafers for each of the Comparative Examples and the Examples. Note that RTO in the referential Example 2 is performed under the same heat treatment conditions as those of the first RTO, except that the maximum temperature reached is 1350° C.

TABLE 1

| | | Oxide | |
|---|---|---|---|
| | | film | |
| | First RTO | removal | Second RTO |
| Referential | Not | Not | Not Performed |
| Example 1 | Performed | Performed | |
| Referential | Performed | Not | Not Performed |
| Example 2 | | Performed | |
| Comparative | Performed | Not | Performed, Heating |
| Example 1 | | Performed | Temperature 1090° C. |
| Example 1 | Performed | Performed | Performed, Heating |
| | | | Temperature 1090° C. |
| Comparative | Performed | Not | Performed, Heating |
| Example 2 | | Performed | Temperature 1150° C. |
| Example 2 | Performed | Performed | Performed, Heating |
| | | | Temperature 1150° C. |
| Comparative | Performed | Not | Performed, Heating |
| Example 3 | | Performed | Temperature 1250° C. |
| Example 3 | Performed | Performed | Performed, Heating |
| | | | Temperature 1250° C. |

“Performed” indicates that the process was carried out.

Production conditions are shown below:

### Crystal Condition

Oxygen Concentration: 1.08×10¹⁸/cm³ to 1.25×10¹⁸/cm³
Nitrogen Concentration: 3.84×10¹⁴/cm³ to 5.16×10¹⁴/cm³
N-type crystal
Atomic vacancies predominant

### Heat Treatment Condition for First RTO

An oxidizing atmosphere with an oxygen partial pressure of 100%
First Maximum Temperature Reached T₁: 1300° C.
First Heating Rate ΔTu₁: 50° C./s
First Holding Time t₁: 30 s.
First Cooling Rate ΔTd₁: 120° C./s

### Conditions for Oxide Film Removal

Clean the wafer surface for 12 s with HF of 15% before the second RTO (after the first RTO)

### Heat Treatment Condition for Second RTO

An oxidizing atmosphere with an oxygen partial pressure of 100%.
Second Maximum Temperature Reached T₂: 1090° C. to 1250° C. (See Table 1).
Second Heating Rate ΔTu₂: 50° C./s
Second Holding Time t₂: 30 s.
Second Cooling Rate ΔTd₂: 120° C./s

### Evaluation

The wafers manufactured for each of the Referential Examples, Comparative Examples, and Examples were evaluated under the evaluation conditions described below.

Specifically, the heat treatment for BMD precipitation was performed twice under the heat treatment conditions for BMD precipitation, and the defect density of 20 nm or more was evaluated using IR tomography as the evaluation equipment.

### Heat Treatment Conditions for BMD Precipitation

An oxidizing atmosphere with an oxygen partial pressure of 100%.
Heating Temperature: 780° C. and Holding Time: 3 hours
Heating Temperature: 1000° C. and Holding Time: 16 hours

### Evaluation Equipment

IR Tomography: LST 2500HD
Laser Power: 10 mW

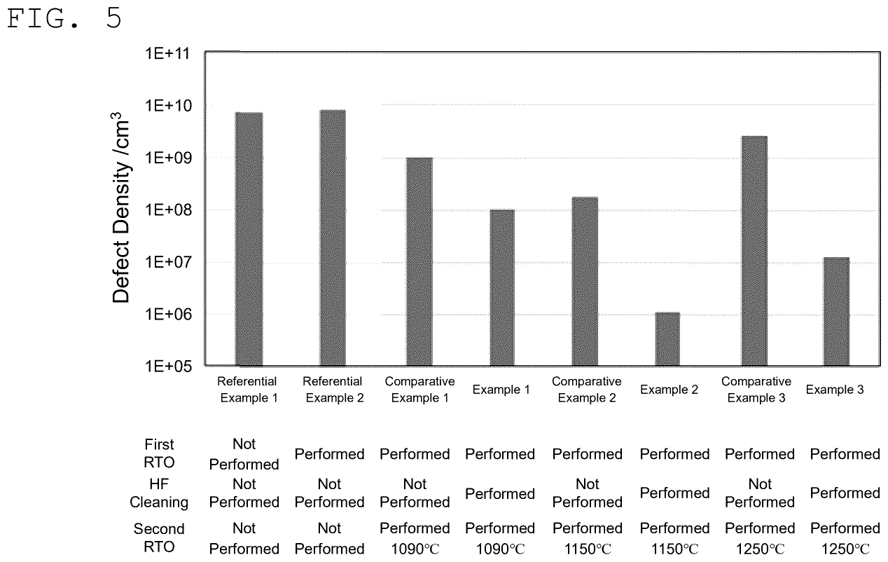

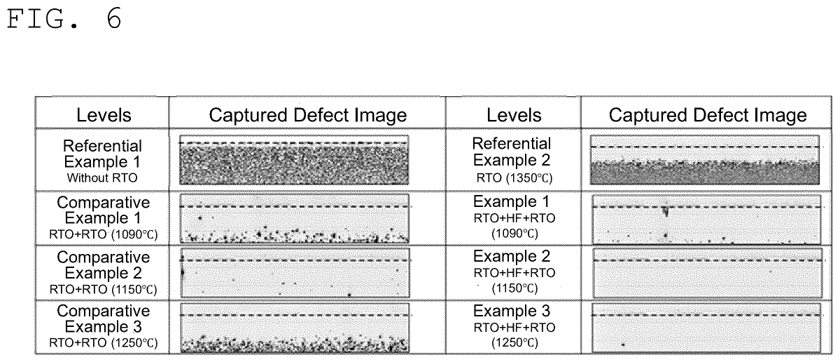

FIG. 5 shows the defect density having 20 nm or more observed by the IR tomography. FIG. 6 shows cross-sectional images of the wafers at a depth of 350 μm from the wafer surface.

FIG. 5 indicates that the defect density of Referential Examples 1 and 2 is the largest, and the defect density was approximately 7×10⁹/cm³. According to the image shown in FIG. 6, in Reference Example 1, points indicating defects are uniformly distributed immediately beneath the wafer surface (see dashed line). In addition, according to the image of Reference Example 2, no defects are observed in the vicinity of the wafer surface (see dashed line), whereas a large number of defects are observed in the bulk region. These images capture BMD precipitates formed during crystal growth, or BMD precipitates attributable to atomic vacancies introduced by a single RTO process.

When the results of Comparative Example 1 (second maximum temperature reached T₂: 1090° C.), Comparative Example 2 (second maximum temperature reached T₂: 1150° C.), Comparative Example 3 (second maximum temperature reached T₂: 1250° C.), Example 1 (second maximum temperature reached T₂: 1090° C.), Example 2 (second maximum temperature reached T₂: 1150° C.), and Example 3 (second maximum temperature reached T₂: 1250° C.) are compared, in which the second RTO was performed in all cases, it is found that the defect densities of Examples 1 to 3, each including the oxide film removal step, tend to be lower than those of Comparative Examples 1 to 3, and are less than 1×10⁸/cm³ in all cases. In addition, when the defect images are compared, it is found that the number of defects observed in Comparative Examples 1 to 3 is significantly reduced in Examples 1 to 3, and that BMD precipitation is effectively suppressed by performing the first RTO, the oxide film removal step, and the second RTO.

### LIST OF REFERENCE SIGNS

10 RTP apparatus
20 Reaction chamber
20a First space
20b Second space
22 Supply port
26 Exhaust port
30 Wafer support
32 Susceptor
34 Rotator
40 Heater
50 Halogen lamp
61 Void
62a, 62b Oxide film
W Wafer (Silicon wafer)

What is claimed is:

1. A method of manufacturing a silicon wafer, comprising:
a first heat treatment step of heating a silicon wafer, which is obtained by slicing and planarizing a single-crystal silicon ingot grown by the CZ method, to a first maximum temperature reached of 1300° C. or higher and 1380° C. or lower in an oxidizing atmosphere having an oxygen partial pressure of 25% to 100%, and holding the silicon wafer at the first maximum temperature reached for 5 s or longer;
an oxide film removal step of cleaning the silicon wafer obtained by the first heat treatment step with hydrofluoric acid; and
a second heat treatment step of heating the silicon wafer, which is obtained by the oxide film removal step, to a second maximum temperature reached of 1050° C. or higher and less than 1300° C. in an oxidizing atmosphere having an oxygen partial pressure of 25% to 100%, and holding the silicon wafer at the second maximum temperature reached for 5 s or longer.

2. The method of manufacturing a silicon wafer of claim 1, further comprising:
a polishing step of polishing a surface and a surface layer of the silicon wafer obtained by the second heat treatment step.

3. The method of manufacturing a silicon wafer of claim 1, wherein
the oxygen partial pressure in the oxidizing atmosphere is 100% for the first heat treatment step and the second heat treatment step.

4. The method of manufacturing a silicon wafer of claim 1, wherein,
in the oxide film removal step, the surface of the silicon wafer obtained by the first heat treatment step is cleaned with a hydrofluoric acid aqueous solution having a concentration of 10% or more for 10 s or more.

5. The method of manufacturing a silicon wafer of claim 1, wherein
the oxygen concentration of the silicon wafer before the first heat treatment step is 1.0×10¹⁸/cm³ to 1.5×10¹⁸/cm³.

6. A silicon wafer that is subjected to a two-stage RTO (Rapid Thermal Oxidation) that interposes a step of removing an oxide film on a surface therebetween,
wherein, after the silicon wafer is held at 730° C. for 3 hours in an oxidizing atmosphere and subsequently held at 1000° C. for 16 hours, a density of defects having a size of 20 nm or greater, as observed by IR tomography, is lower than 1.0×10⁸/cm³.
